(19) United States
(12) Patent Application Publication
(10) Pub. No.: US 2003/0100153 A1
(43) Pub. Date: May 29, 2003

(54) Method of manufacturing a semiconductor memory, and method of manufacturing a semiconductor device comprising the semiconductor memory

(75) Inventor: Yuichi Kunori, Tokyo (JP)

Correspondence Address: MCDERMOTT, WILL & EMERY, 600 13th Street, N.W., WASHINGTON, DC, 20005-3096, US

(73) Assignee: Mitsubishi Denki Kabushiki Kaisha

(21) Appl. No.: 10/212,706

(22) Filed: Aug. 7, 2002

(30) Foreign Application Priority Data
Nov. 27, 2001 (JP) 2001-360635

(51) Int. Cl. H01L 21/336; H01L 21/8238

(52) U.S. Cl. 438/197; 438/287; 438/216

(57) ABSTRACT

A method of manufacturing a semiconductor memory of a MONOS structure includes depositing an ONO film of a first silicon oxide film, a silicon nitride film and a second silicon oxide film on a substrate. Thereafter, a first conductive layer is formed on the ONO film, and at least the first conductive layer, the second silicon oxide film, and the silicon nitride film are etched to form a groove portion. Thereafter, ions are implanted into the substrate in a bottom portion of the groove portion to form a bit line. Then, an insulation film is deposited on the substrate, and the film thickness of the insulation film is reduced by a CMP method to leave the insulation film within the groove portion. Thereafter, a second conductive layer is deposited on the first conductive layer and the insulation film to form a word line.

### BACKGROUND OF THE INVENTION

1. Field of the Invention

The present invention relates to a method of manufacturing a non-volatile semiconductor memory, and more particularly, to a method of manufacturing a MONOS-type semiconductor memory.

2. Description of the Related Art

FIG. 41 is a cross sectional view showing a cell in a MONOS-type semiconductor memory described in U.S. Pat. No. 5,966,603 and generally indicated at 600. FIGS. 42 through 45 are cross sectional views showing steps for manufacturing the semiconductor memory 600. The steps for manufacturing the semiconductor memory 600 include the following steps 1 through 4.

Step 1: As shown in FIG. 42, a silicon substrate 601 is prepared. Following this, an ONO film (Oxide/Nitride/Oxide film) 605 of a silicon oxide film 602, a silicon nitride film 603 and a silicon oxide film 604, is deposited on the silicon substrate 601 by a CVD method. The thickness of each film is 15 nm or thinner.

Step 2: As shown in FIG. 43, a resist mask 606 is formed on the ONO film 605 so that the resist mask 606 covers an area where a transistor will be formed later. Following this, using the resist mask 606 as an etching mask, the silicon oxide film 604 and the silicon nitride film 603 are etched. At this stage, the silicon oxide film 602 is partially over-etched.

Step 3: As shown in FIG. 44, n-type ions 607 such as phosphorus are implanted using the resist mask 606 as an implantation mask. As a result, diffusion bit lines (BL) 608 and 609 are formed on the silicon substrate 601.

Step 4: As shown in FIG. 45, after removing the resist mask 606 through dry etching, the silicon substrate 601 at the surface of the diffused bit lines 608 and 609 is thermally oxidized by a LOCOS method, whereby a LOCOS isolation 610 is formed. At last, polycrystalline silicon is deposited and processed so that a word line (WL) 611 is formed.

Through the steps above, the MONOS-type semiconductor memory 600 shown in FIG. 41 is completed. In the semiconductor memory 600, electrons are introduced and held in the silicon nitride film 603 in two areas 612 and 613. That means writing to the semiconductor memory 600 is done in the two areas 612 and 613 (2 bits).

FIG. 46 shows one example of the writing step. Voltage of 0 V is impressed to the bit line 608, and 5.5 V to the bit line 609 as well as 11 V to the word line 611. As a result, electrons 614 move from the bit line 608 to the bit line 609, and the electrons, now becoming hot electrons in the vicinity of the area 613 are attracted by the word line 611, travel into and accumulated in the silicon nitride film 603.

However, since the resist mask 606 is formed directly on the ONO film 605 and removed through the manufacturing steps above, a residue of a resist material remains on the ONO film 605 after removal of the resist mask 606 and serves as a cause to degrade the reliability of the semiconductor memory 600. In addition, since the resist mask 606 is removed by dry etching, the ONO film 605 gets damaged by etching eventually causing defective operations of the semiconductor memory 600.

Further, while the ONO film 605 is to serve as a gate oxide film of a transistor, since the surface of the silicon oxide film 604 is etched during pretreatment prior to the LOCOS step, control of the thickness of the gate oxide film is difficult.

Further, use of the LOCOS isolation subjects an edge portion of the silicon nitride film 603 to stress due to bird's beak, thereby creating a defect in the silicon nitride film 603. In the case of the MONOS-type semiconductor memory 600, since writing occurs in the edge portion, the defect exerts an adverse influence over writing.

Still further, since the LOCOS isolation is thick and is formed after implantation of the ions into the bit lines 608 and 609, the bit lines 608 and 609 spread below the bird's beak in the resulting structure.

### SUMMARY OF THE INVENTION

An object of the present invention is to provide a method of manufacturing the MONOS-type semiconductor memory 600 to ensure high controllability of the film thickness of the ONO film 605 without leaving any residue in the ONO film 605 or damage on the ONO film 605.

A Further object of the present invention is to provide a manufacturing method of preventing deterioration in performance of the semiconductor memory 600 caused by using LOCOS isolation.

A method of manufacturing a semiconductor memory of a MONOS structure includes depositing an ONO film of a first silicon oxide film, a silicon nitride film and a second silicon oxide film on a substrate, forming a first conductive layer on the ONO film, forming a resist mask on the first silicon oxide film, etching at least the first conductive layer, the second silicon oxide film and the silicon nitride film to form a groove portion, implanting ions into the substrate in a bottom portion of the groove portion to form a bit line, depositing an insulation film on the substrate and reducing the film thickness of the insulation film by a CMP method to leave the insulation film within the groove portion, and depositing a second conductive layer on the first conductive layer and the insulation film to thereby form a word line. Since the conductive layer is formed after forming the ONO film having a charge accumulation layer, the photo resist layer does not directly contact the ONO film.

In addition, a method of manufacturing a semiconductor device having a semiconductor memory of a MONOS structure and a peripheral transistor includes defining a semiconductor memory forming area and a peripheral transistor forming area on a semiconductor substrate, depositing a first silicon oxide film, a silicon nitride film and a silicon film on the substrate, forming a resist mask on the silicon film, etching the silicon film, the silicon nitride film and the first silicon oxide film in the peripheral transistor forming area, oxidizing the substrate in the peripheral transistor forming area to form a gate oxide film and also oxidizing the silicon film to form a second silicon oxide film in order to form an ONO film, and forming a conductive layer on the gate oxide film and the ONO film.

### BRIEF DESCRIPTION OF THE DRAWINGS

FIG. 1 is a cross sectional view of the semiconductor memory according to the first preferred embodiment of the present invention.

FIGS. 2 through 10 are cross sectional views showing steps for manufacturing the semiconductor memory according to the first preferred embodiment of the present invention.

FIG. 11 is a cross sectional view of the semiconductor memory according to the second preferred embodiment of the present invention.

FIGS. 12 through 16 are cross sectional views showing steps for manufacturing the semiconductor memory according to the second preferred embodiment of the present invention.

FIG. 17 is a cross sectional view of the semiconductor device according to the third preferred embodiment of the present invention.

FIGS. 18 through 26 are cross sectional views showing steps for manufacturing the semiconductor device according to the third preferred embodiment of the present invention.

FIG. 27 is a cross sectional view of the semiconductor device according to the fourth preferred embodiment of the present invention.

FIGS. 28 through 31 are cross sectional views showing steps for manufacturing the semiconductor device according to the fourth preferred embodiment of the present invention.

FIG. 32 is a cross sectional view of the semiconductor device according to the fifth preferred embodiment of the present invention.

FIGS. 33 through 40 are cross sectional views showing steps for manufacturing the semiconductor device according to the fifth preferred embodiment of the present invention.

FIG. 41 is a cross sectional view of the conventional semiconductor memory.

FIGS. 42 through 46 are cross sectional views showing steps for manufacturing the conventional semiconductor memory.

### DETAILED DESCRIPTION OF THE PREFERRED EMBODIMENTS

First Preferred Embodiment

FIG. 1 is a cross sectional view showing a MONOS-type semiconductor memory according to a first preferred embodiment of the present invention indicated in its entirety by 100. The semiconductor memory 100 includes a semiconductor substrate 1 of silicon for instance. On the semiconductor substrate 1, an ONO film (Oxide/Nitride/Oxide film) 5 of a silicon oxide film 2, a silicon nitride film 3 and a silicon oxide film 4, is disposed. A conductive layer 6 of polycrystalline silicon for instance is formed on the ONO film 5. A groove portion is formed in the ONO film 5, and an insulation film 12 of oxide silicon for instance is buried as an insulation isolation region. Bit lines 10 and 11 are formed on the semiconductor substrate 1 under the insulation film 12. Further, a conductive layer 13 of polycrystalline silicon for instance is formed on the insulation film 12 and the conductive layer 6. The conductive layer 6 and the conductive layer 13 function as a word line.

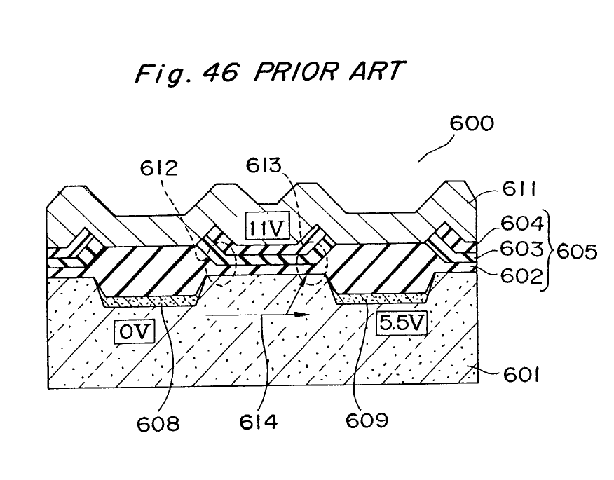

The operation principles of the MONOS-type semiconductor memory 100 are similar to those shown in FIG. 46. As predetermined voltages are applied to the bit lines and word lines, electrons are written in or read from the silicon nitride film 3 in an area 30.

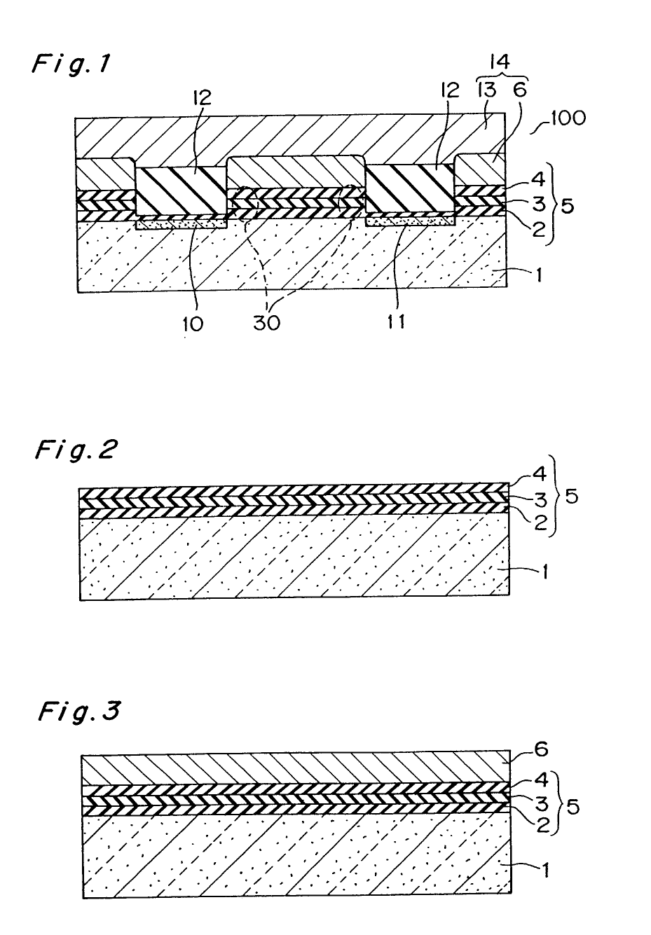

A method of manufacturing the MONOS-type semiconductor memory 100 will be described with reference to FIGS. 2 through 6. The manufacturing method includes the following steps 1 through 6.

Step 1: As shown in FIG. 2, a silicon substrate 1 of p-type silicon for instance is prepared. A p-type well region may be formed within the substrate.

Following this, the silicon oxide film 2, the silicon nitride film 3 and the silicon oxide film 4 are successively formed by CVD method on the semiconductor substrate 1. The film thickness of each film is 15 nm or thinner. These layers form the ONO film 5.

Step 2: As shown in FIG. 3, a conductive layer 6 of polycrystalline silicon doped with impurities for instance is formed on the ONO film 5 by CVD method. In this case, after the ONO film 5 is formed, the conductive layer 6 is formed without surface treatment of the ONO film 5. The film thickness of the conductive layer 6 is preferably from about 10 nm to 200 nm, and it is desirable that the conductive layer 6 is made of the same material as the one of the conductive layer 13 which will be formed at a later step.

The thickness of the conductive layer 6 as well as the that of the silicon oxide film 4 and the silicon nitride film 3 define the film thickness of the insulation film 12 to isolate the bit lines from the word lines. Considering that the film thickness of the insulation film 12 is at least about 30 nm, the film thickness of the conductive layer 6 is at least about 10 nm.

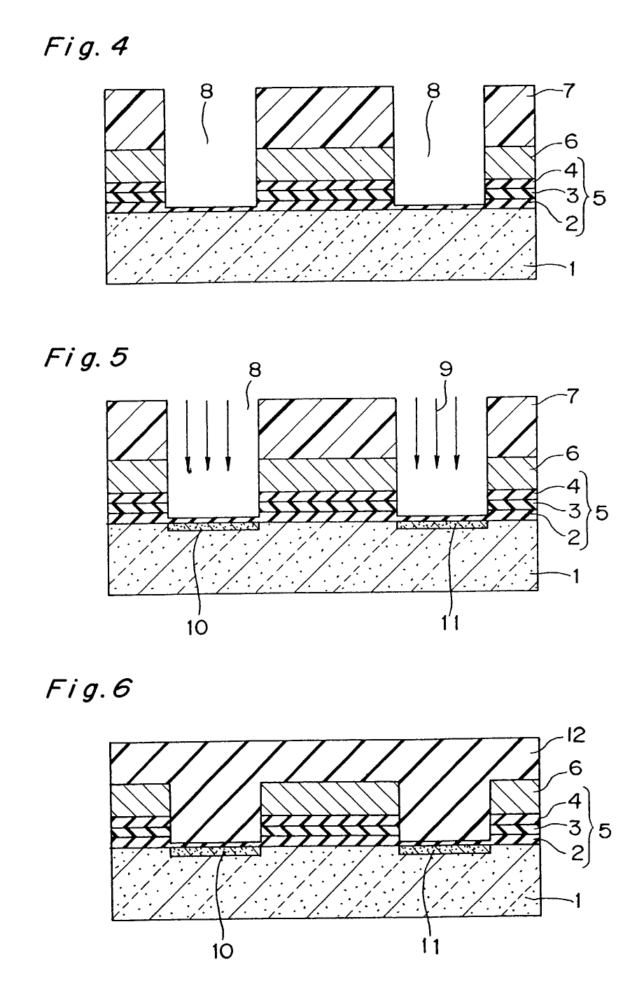

Step 3: As shown in FIG. 4, after depositing a photo resist layer on the conductive layer 6, a resist mask 7 is formed using a photolithographic technique. Following this, using the resist mask 7 as an etching mask, the conductive layer 6, the silicon oxide film 4 and the silicon nitride film 3 are dry etched to form a groove portion 8. At this dry etching step, the silicon oxide film 2 may be over-etched.

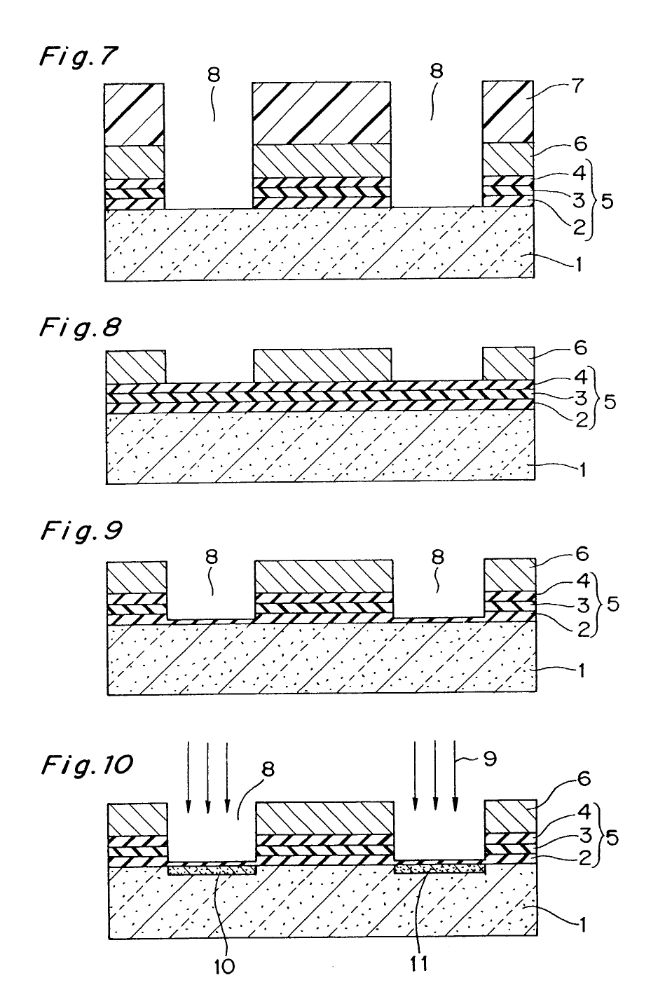

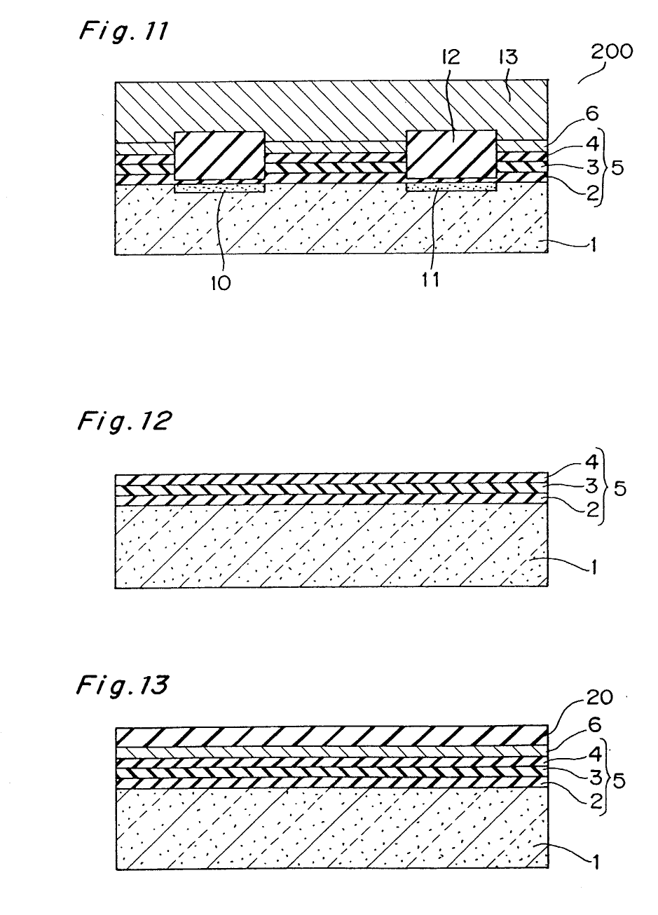

Alternatively, as shown in FIG. 7, the silicon nitride film 3 may be entirely etched away so as to expose the surface of the semiconductor substrate 1 (This equally applies to preferred embodiments described below.).

Step 4: As shown in FIG. 5, using the resist mask 7 as an implantation mask, n-type impurities are implanted into the semiconductor substrate 1 in a bottom portion of the groove portion 8. As the n-type impurities, arsenic, phosphorus, boron or the like are used for instance. As a result, the bit lines 10 and 11 are formed in the semiconductor substrate 1 in the bottom portion of the groove portion 8.

Step 5: As shown in FIG. 6, after removing the resist mask 7, the insulation film 12 of TEOS for example is formed on the entire surface. The insulation film 12 is formed by a CVD method, for instance.

Step 6: Using a CMP method, the thickness of the insulation film 12 is reduced from the top surface to leave the insulation film 12 only within the groove portion 8. After removing a native oxide film formed at the surface of the conductive layer 6 using hydrofluoric acid or the like, the conductive layer 13 of polycrystalline silicon for instance doped with impurities is then deposited by a CVD method on the entire surface. Considering the ease of processing the conductive layer 13, the film thickness of the conductive layer 13 is preferably 0.200 nm or thinner. Further, the conductive layer 13 is patterned to form a word line. This completes the MONOS-type semiconductor memory 100 shown in FIG. 1. In the semiconductor memory 100, a word line 14 consists of the conductive layer 6 and the conductive layer 13.

It is noted that, at the steps 3 through 5, the steps shown in FIGS. 8 through 10 may be performed instead of the steps shown in FIGS. 4 through 6.

That is, at the steps shown in FIGS. 8 through 10, the resist mask 7 is removed after patterning the conductive layer 6 using the resist mask 7 as shown in FIG. 8. Following this, as shown in FIG. 9, the silicon oxide film 4 and the silicon nitride film 3 are etched using the conductive layer 6 as an etching mask so that the groove portion 8 is formed. The n-type impurities are thereafter introduced as shown in FIG. 10 to form bit lines 10 and 11.

These steps are applicable to a manufacturing method according to a second preferred embodiment to be described below.

As described above, according to this manufacturing method the conductive layer 6 is formed after forming the ONO film 5 comprising a charge accumulation layer (silicon nitride film). Since the photo resist layer does not directly contact the ONO film 5 contrary to conventional methods, it is possible to prevent the ONO film 5 from getting contaminated by a resist residue.

In addition, since plasma is not irradiated upon the ONO film 5 during removal of the photo resist layer contrary to conventional methods, the ONO film 5 is not damaged.

Further, since the insulation film 12 is buried in the groove portion 8 to thereby form an isolation structure instead of using LOCOS isolation, it is possible to obviate occurrences of defects created in the silicon nitride film 3 due to bird's beak.

Moreover, spreading of the bit lines 10 and 11 toward below the insulation film 12 is prevented so that the size of the semiconductor memory 100 is reduced.

Second Preferred Embodiment

FIG. 11 is a cross sectional view showing a MONOS-type semiconductor memory according to a second preferred embodiment of the present invention indicated in its entirety by 200. In FIG. 11, the same reference symbols as those used in FIG. 1 denote the same or corresponding portions. Although the semiconductor memory 200 is approximately similar to the semiconductor memory 100 described above, a manufacturing method is different.

The method of manufacturing the semiconductor memory 200 according to the second preferred embodiment will be described with reference to FIGS. 12 through 16. The manufacturing method includes the following steps 1 through 6.

Step 1: As shown in FIG. 12, the semiconductor substrate 1 is prepared, and the ONO film 5 composed of the silicon oxide film 2, the silicon nitride film 3 and the silicon oxide film 4 is disposed on the silicon substrate 1.

Step 2: As shown in FIG. 13, a conductive layer 6 of polycrystalline silicon or the like and a stopper layer 20 of silicon nitride or the like are successively formed on the ONO film 5. The stopper layer 20 is made of a different material from that of the conductive layer 6. As in the case of the film thickness of the conductive layer 6 according to the first preferred embodiment described above, it is desirable that the total film thickness of the conductive layer 6 and the stopper layer 20 is at least 10 nm. Further, considering a CMP step, the film thickness of the stopper layer 20 is preferably twice as thick as the ONO film 5 or thicker.

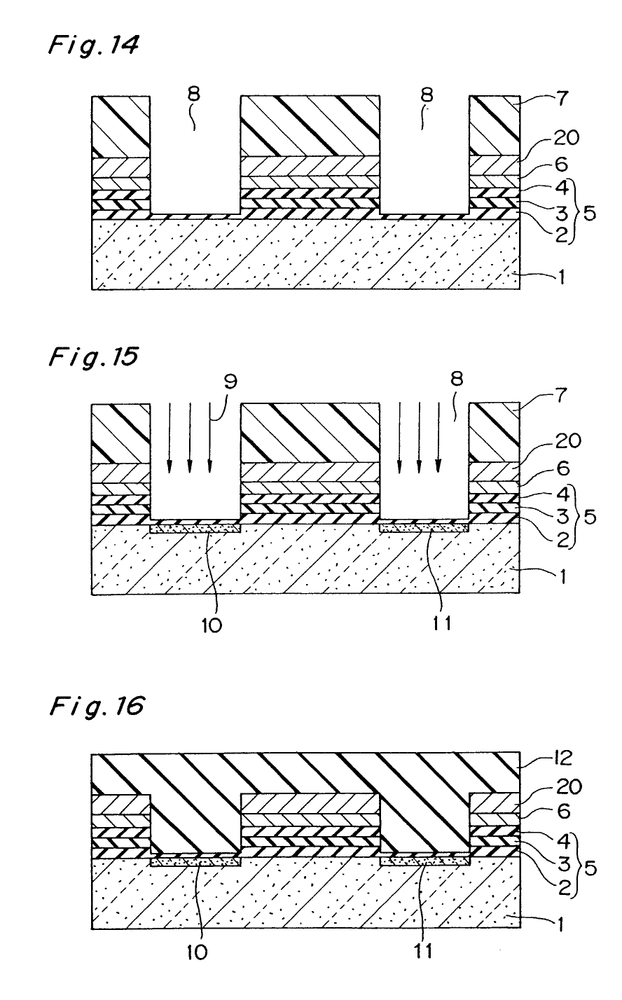

Steps 3-5: As shown in FIGS. 14, 15 and 16, steps similar to the steps 3 through 5 according to the first preferred embodiment described above are performed.

Step 6: Using a CMP method, the film thickness of the insulation film 12 is reduced from the top surface, to leave the insulation film 12 only within the groove portion 8. At the CMP step, the stopper layer 20 is used as an etching stopper layer and CMP is continued until the surface of the stopper layer 20 is exposed. Following this, the stopper layer 20 is removed using heated phosphoric acid for instance. Since a difference in level is created between the insulation film 12 and the conductive layer 6 by removing stopper layer 20, the thickness of the stopper layer 20 is desired to be relatively thin, i.e., 300 nm or less.

After removing a native oxide film formed on the surface of the conductive layer 6 using hydrofluoric acid for instance, the conductive layer 13 is thereafter deposited on the entire surface. Further, the conductive layer 13 is patterned to form a word line. This completes the MONOS-type semiconductor memory 200 which is shown in FIG. 11.

As described above, the stopper layer 20 is used as an etching stopper layer at the CMP step in the manufacturing method according to the second preferred embodiment, and therefore, the surface of the ONO layer 5 may not be directly polished at the CMP step. This reduces stress to be imposed on the ONO 5 film and accordingly reduces damage.

In addition, as compared with the case of formation of relatively thicker stopper layer alone (the thickness is the sum of the thickness of the conductive layer 6 and that of the stopper layer 20) without forming the conductive layer 6, a smaller difference in level between the insulation film 12 and the conductive layer 6 is obtained when the stopper layer 20 is removed.

Third Preferred Embodiment

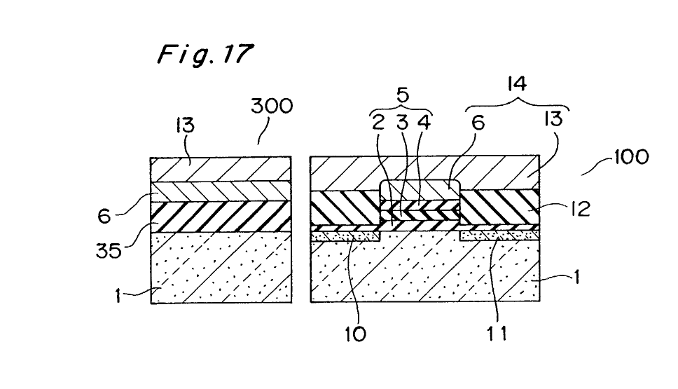

FIG. 17 is a cross sectional view of a semiconductor device which includes a semiconductor memory 100 according to a third preferred embodiment and a peripheral transistor 300 used in a peripheral circuit. In FIG. 17, the same reference symbols as those used in FIG. 1 denote the same or corresponding portions, and the semiconductor memory 100 is the semiconductor memory according to the first preferred embodiment. Further, isolation area formed by an oxide film or the like are appropriately formed around the peripheral transistor 300 and the like (not shown).

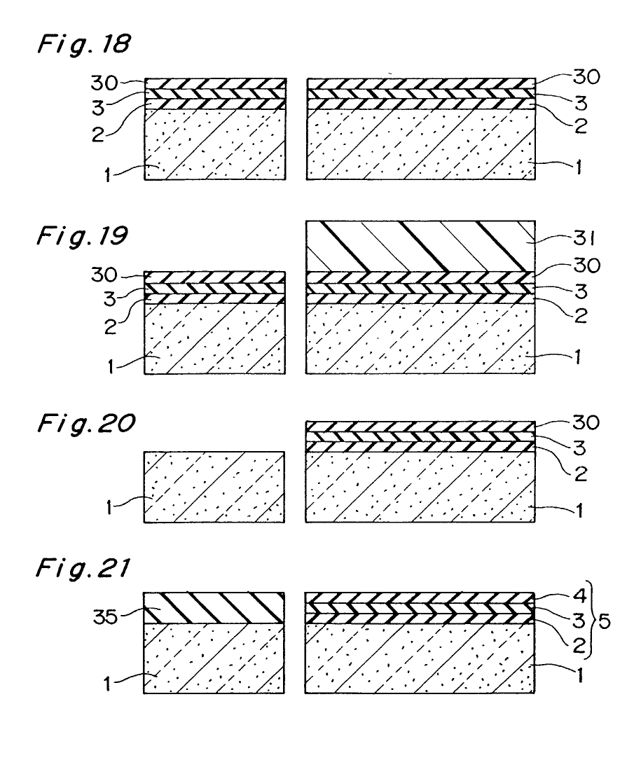

A method of manufacturing the semiconductor device according to the third preferred embodiment will be described with reference to FIGS. 18 through 26. In FIGS. 18 through 26, shown on the left-hand side is a cross section of the peripheral transistor 300, whereas shown on the right-hand side is a cross section of the semiconductor memory 100. The manufacturing method includes the following steps 1 through 10.

Step 1: As shown in FIG. 18, the semiconductor substrate 1 is prepared, and the silicon oxide film 2, the silicon nitride film 3 and a silicon film 30 are successively formed by a CVD method on the semiconductor substrate 1. The silicon film 30 is made of amorphous silicon or polycrystalline silicon, which is doped at a low concentration (3×10²⁰/cm³ or lower) or not doped.

Since the silicon film 30 becomes the silicon oxide film 4 after oxidized at a later step, the thickness of the silicon film 30 is set so that the silicon oxide film 4 may have preferable film thickness.

Step 2: As shown in FIG. 19, a photo resist layer 31 is formed in a memory forming area.

Step 3: As shown in FIG. 20, the silicon film 30 and the silicon nitride film 3 in a transistor forming area are removed by dry etching. Following this, the silicon oxide film 2 is removed using hydrofluoric acid solution. Further, the resist mask 31 in the memory forming area is removed by plasma etching.

At this step, the silicon oxide film 2 in the transistor forming area may be removed after removing the resist mask 31. This realizes no plasma irradiation upon the semiconductor substrate 1 in the transistor forming area and prevents damage to the semiconductor substrate 1 during removal of the resist mask 31. Hence, the reliability of the eventually obtained transistor 300 improves.

Step 4: As shown in FIG. 21, a residue of the resist mask 30 is removed through ammonia hydrolysis (R pretreatment). The silicon film 30 in the memory forming area is not etched away at all during this treatment. This is followed by thermal oxidation of forming a gate oxide film 35 at the surface in the transistor forming area. At this step, in the memory forming area, the surface of the semiconductor substrate 1 covered with the silicon nitride film 3 is not oxidized, whereas the silicon film 30 on the silicon nitride film 3 is oxidized and consequently becomes the silicon oxide film 4. Control of the thickness of the silicon film 35 permits to obtain the silicon oxide film 4 of desired film thickness. That is, if the silicon film 30 is wet oxidized, the film thickness of the silicon oxide film 4 becomes approximately twice as thick as the silicon film 30 as it is before oxidation. Thus, by defying an oxidation condition, the thickness of the silicon oxide 5 to be formed is precisely controlled.

Besides, even if a defect is created in the silicon film 30 at the step of removing the resist mask 31, it is possible to remove such a defect at a thermal oxidation step, by thermally oxidizing the silicon film 30 of amorphous silicon or polycrystalline silicon to form the silicon oxide film 4.

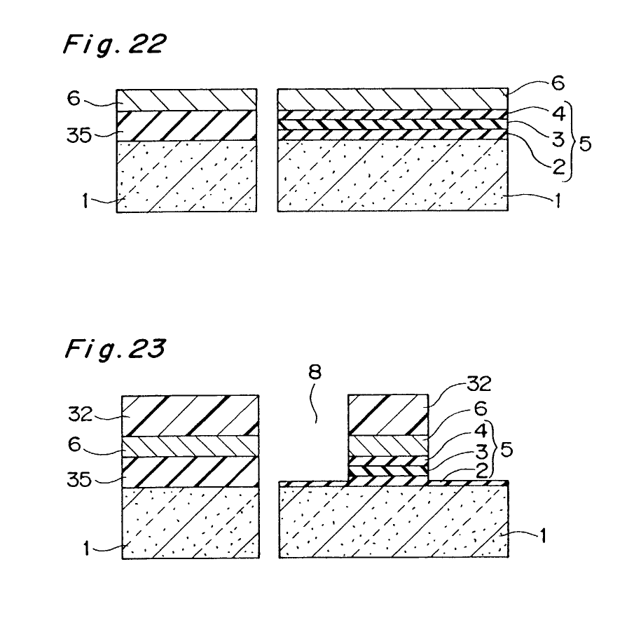

Step 5: As shown in FIG. 22, the conductive layer 6 of polycrystalline silicon or the like is deposited on the entire surface.

Step 6: As shown in FIG. 23, using a resist mask 32, the memory forming area is etched to form the groove portion 8.

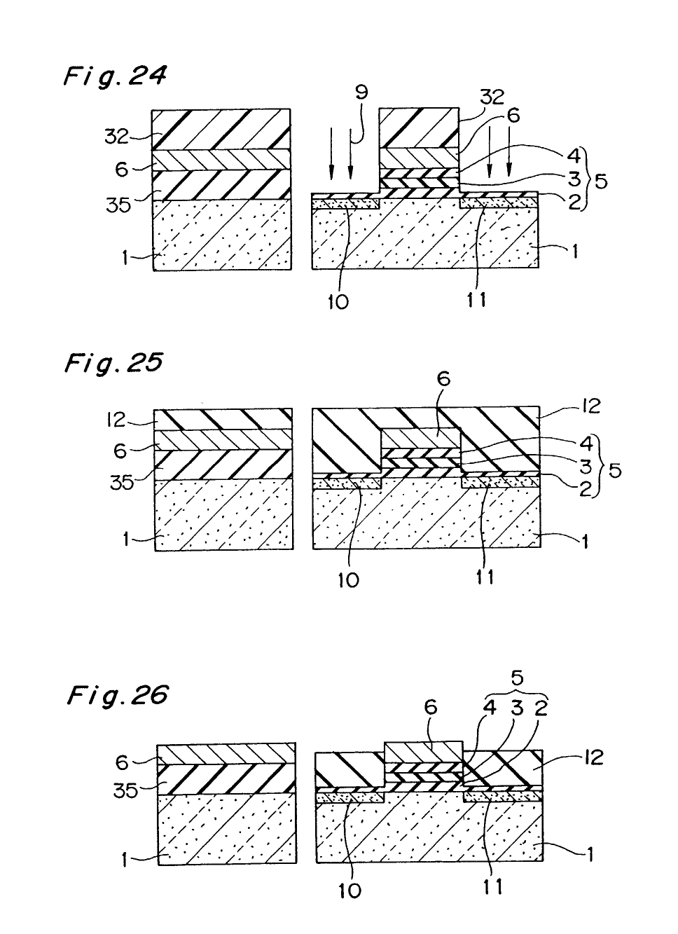

Step 7: As shown in FIG. 24, impurities of arsenic or the like are implanted into a bottom portion of the groove portion 8, and the bit lines 10 and 11 are consequently formed.

Step 8: As shown in FIG. 25, after removing the resist mask 32, the insulation film 12 of oxide silicon for instance is deposited on the entire surface.

Step 9: Using a CMP method, the thickness of the insulation film 12 is reduced from the top surface. The insulation film 12 is left inside the groove portion 8 in the memory forming area, whereby the isolation regions are formed.

Step 10: At last, after depositing the conductive layer 13 of polycrystalline silicon or the like for instance doped with impurities, patterning is performed to thereby form the word line 14. The word line 14 is consisted of the conductive layer 6 and the conductive layer 13.

Through the steps above, the semiconductor device including the semiconductor memory 100 and the peripheral transistor 300 shown in FIG. 17 is completed.

Use of the manufacturing method according to the third preferred embodiment makes it possible to manufacture the peripheral transistor while preventing contamination of or damage to the ONO film 5.

Fourth Preferred Embodiment

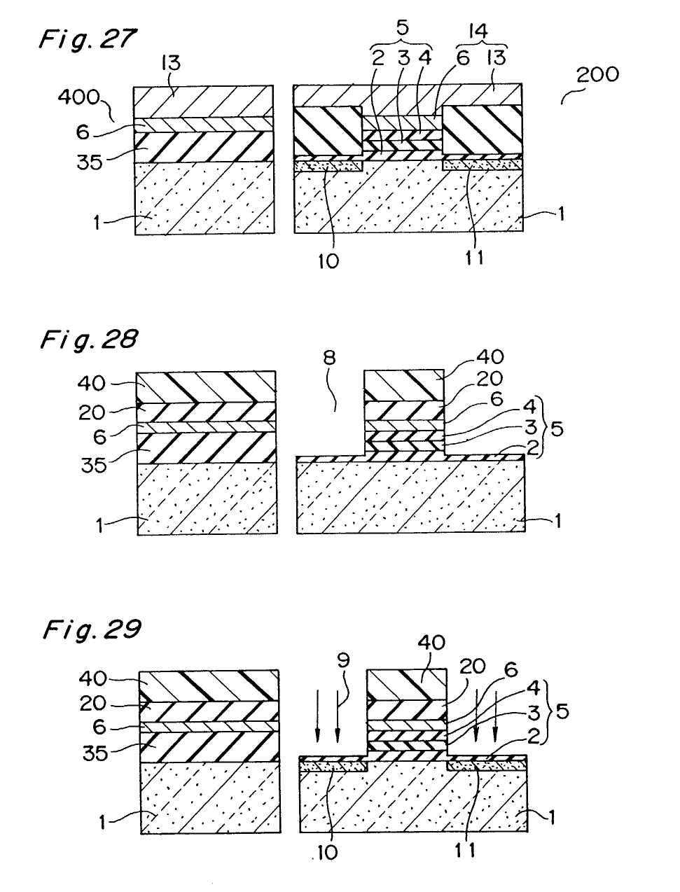

FIG. 27 is a cross sectional view of a semiconductor device including a semiconductor memory 100 according to a fourth preferred embodiment and a peripheral transistor 400 to be used in a peripheral circuit. In FIG. 27, the same reference symbols as those used in FIG. 11 denote the same or corresponding portions, and the semiconductor memory 200 is the semiconductor memory according to the second preferred embodiment. Further, isolation regions formed by an oxide film or the like are formed around the peripheral transistor 400 and the like appropriately (not shown).

A method of manufacturing the semiconductor device according to the fourth preferred embodiment will be described with reference to FIGS. 27 through 31. In FIGS. 27 through 31, shown on the left-hand side is a cross section of the peripheral transistor 400, whereas shown on the right-hand side is a cross section of the semiconductor memory 200. The manufacturing method includes the following steps 1 through 10.

Step 1: Through approximately the same steps as shown in FIGS. 18 through 23 according to the third preferred embodiment described above, a structure as that shown in FIG. 28 is obtained. According to the fourth preferred embodiment, however, at the step shown in FIG. 22, a stopper layer 20 of silicon nitride or the like for instance is formed on a conductive layer 6.

Step 2: As shown in FIG. 29, using a resist mask 40 as an implantation mask, impurities such as arsenic are implanted into a bottom portion of the groove portion 8, and the bit lines 10 and 11 are consequently formed.

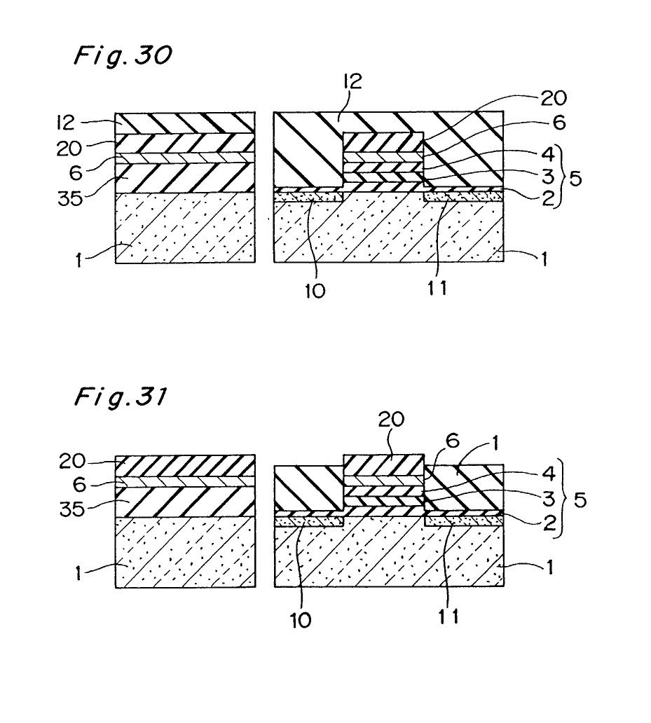

Step 3: As shown in FIG. 30, after removing the resist mask 40, the insulation film 12 consisting of oxide silicon for instance is deposited on the entire surface.

Step 4: As shown in FIG. 31, using a CMP method, the thickness of the insulation film 12 is reduced from the top surface. The insulation film 12 is left inside the groove portion 8 in the memory forming area, whereby the isolation areas are formed.

Step 5: At last, after depositing the conductive layer 13, patterning is performed to thereby form a word line 14. The word line 14 consists of the conductive layer 6 and the conductive layer 13. Through the steps above, the semiconductor device shown in FIG. 27 including the semiconductor memory 200 and the peripheral transistor 400 is completed.

Use of the manufacturing method according to the fourth preferred embodiment makes it possible to manufacture the peripheral transistor while preventing contamination of or damage to the ONO film 5. Further, it is possible to prevent damage on the ONO film 5 at the CMP step.

Fifth Preferred Embodiment

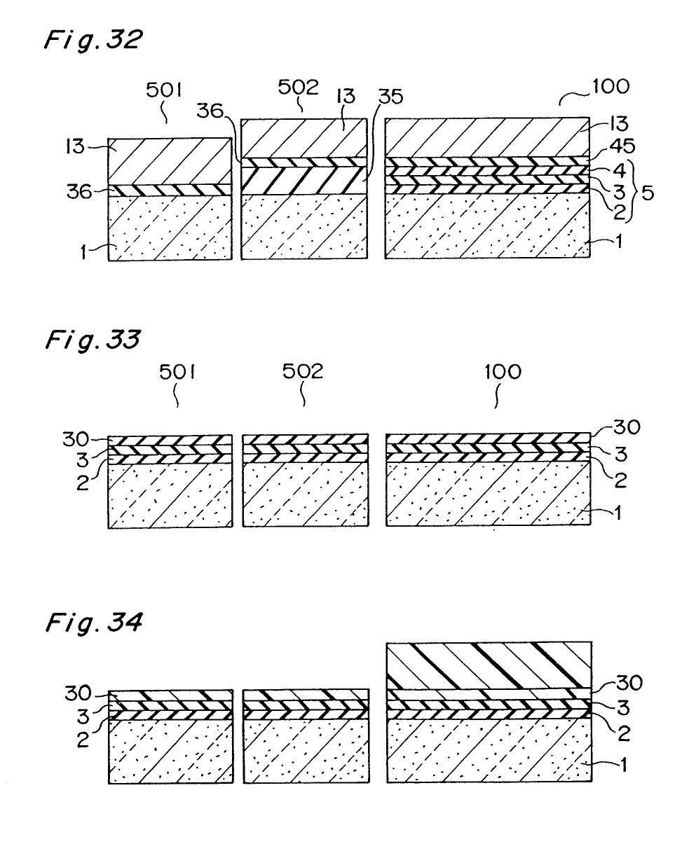

FIG. 32 is a cross sectional view of a semiconductor device including a semiconductor memory 100 according to a fifth preferred embodiment and two peripheral transistors 501 and 502 to be used in a peripheral circuit. In FIG. 32, the same reference symbols as those used in FIG. 1 denote the same or corresponding portions, and the semiconductor memory 100 is the semiconductor memory according to the first preferred embodiment. The thickness of a gate oxide film of the peripheral transistor 501 is different from that of the peripheral transistor 502. In addition, isolation regions formed by an oxide film or the like are formed around the peripheral transistors 501, 502 and the like appropriately (not shown).

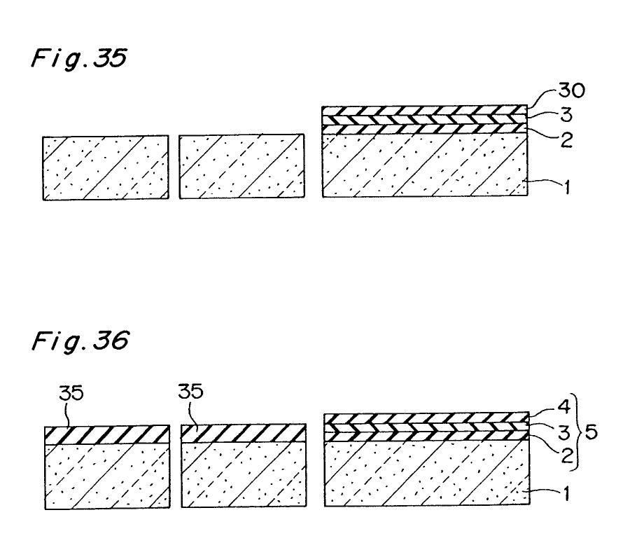

A method of manufacturing the semiconductor device according to the fifth preferred embodiment will be described with reference to FIGS. 33 through 40. In FIGS. 33 through 40, shown on the left-hand side are cross sections of the two peripheral transistors 501 and 502, whereas shown on the right-hand side are cross sections of the semiconductor memory 100. The manufacturing method includes the following steps 1 through 8.

Steps 1-4: Through approximately the same steps as the steps 1 through 4 (FIGS. 18 through 23) according to the third preferred embodiment described above, a structure as that shown in FIG. 36 is obtained. At these steps, the gate oxide films 35 having the same film thickness are formed also on the semiconductor substrate 1 of the two peripheral transistors 501 and 502. The thickness of the gate oxide films 35 however is thinner than in the third preferred embodiment (as there is only one type of film thickness with respect to the gate oxide film of the peripheral transistor according to the third preferred embodiment).

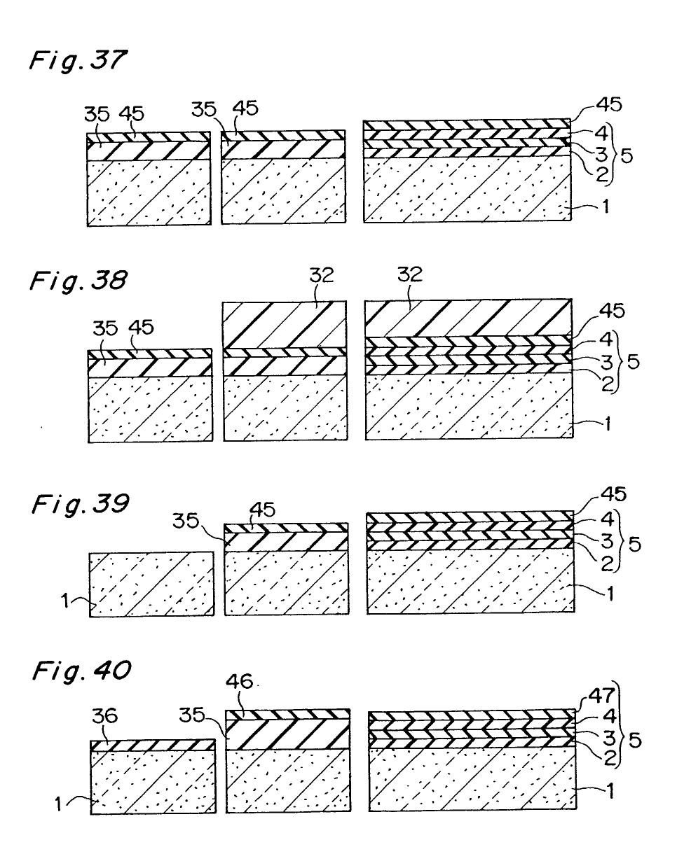

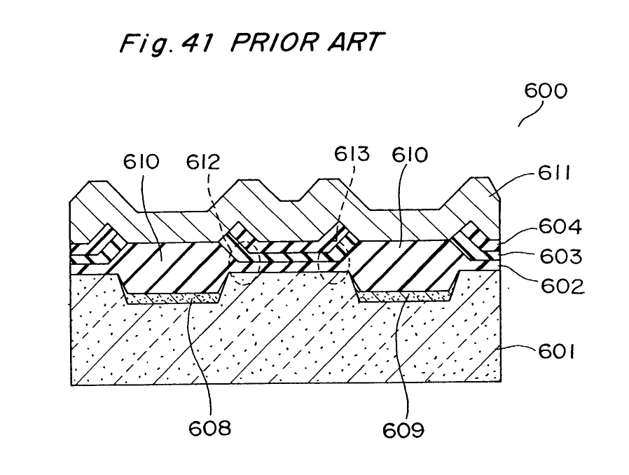

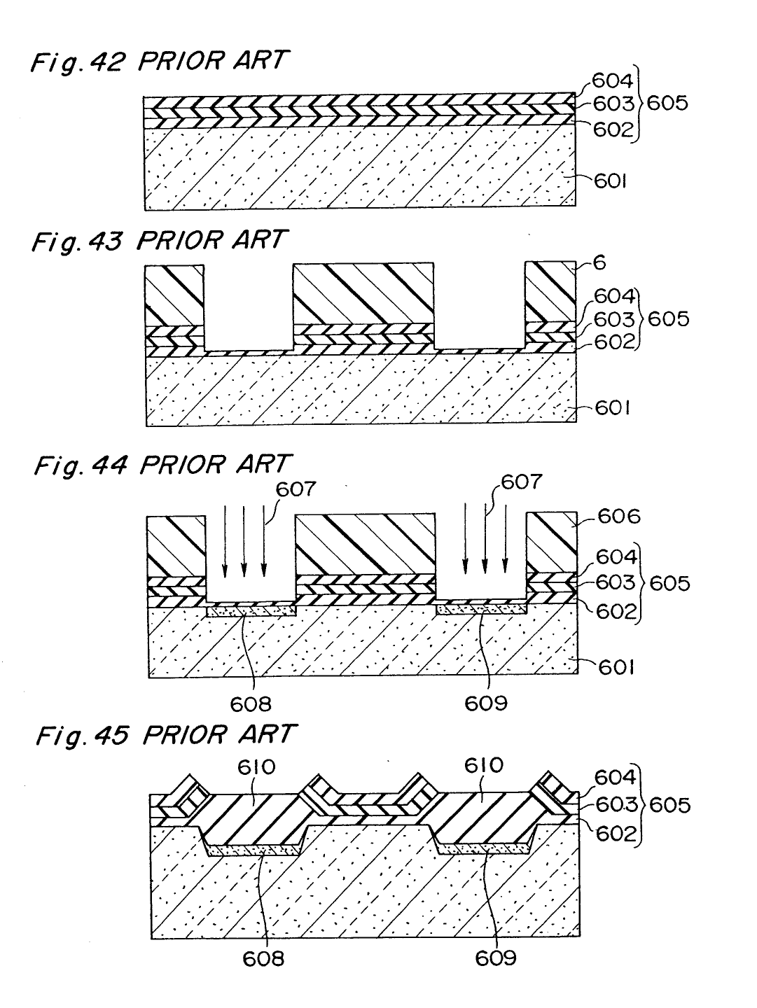

Step 5: As shown in FIG. 37, a silicon film 45 of polycrystalline silicon or the like for instance is deposited on the entire surface.

Step 6: As shown in FIG. 38, a photo resist layer is formed on the entire surface and patterned, thereby forming a resist mask 32 exposing only an area for formation of the peripheral transistor 501.

Step 7: As shown in FIG. 39, the gate oxide film 35 and the silicon film 45 in the area for formation of the peripheral transistor 501 are removed by etching. Following this, the resist mask 32 is removed.

Alternatively, the resist mask 32 may be removed after removal of the silicon film 45 in the area for formation of the peripheral transistor 501. Following this, the gate oxide film 35 in the area for formation of the peripheral transistor 501 may be removed using the silicon film 45 as an etching mask.

Step 8: As shown in FIG. 40, the surface of the semiconductor substrate 1 in the area for formation of the peripheral transistor 501 is thermally oxidized to form a gate oxide film 36. At the thermal oxidation step, the silicon film 45 as well is oxidized, so that a gate oxide film 46 of the peripheral transistor 502 and a silicon oxide film 47 of the semiconductor memory (portions of the top layer film of the ONO film) are formed. At this step, the surface of the semiconductor substrate 1 in the peripheral transistor 502 as well is oxidized even on a small scale. Meanwhile, the silicon film 45 should be completely oxidized so that the silicon film 45 becomes the silicon oxide film 47. In the peripheral transistor 502, the total thickness of the gate oxide films 35 and 46 is the thickness of the gate oxide film. Hence, it is ensured that the thickness of the gate oxide film of the peripheral transistor 501 is different from that of the peripheral transistors 502.

With respect to such a semiconductor device, it is necessary to control the thickness of the silicon film 45, the thermal oxidation condition or the like in such a manner that the thickness of the gate oxide film 36 of the peripheral transistor 501, the thickness of the gate oxide films 35 and 46 of the peripheral transistor 502 as well as the thickness of the silicon oxide films 4 and 47 in the top layer of the ONO film eventually become as desired.

Following this, a conductive layer 13 is deposited on the entire surface and patterned, whereby a word line is formed. This completes the semiconductor device including the semiconductor memory 100 and the two types of peripheral transistors 501 and 502 with the different thickness of the gate film.

In the manufacturing method according to the fifth preferred embodiment, the photo resist layer is not formed directly on the gate oxide films or the ONO film. Hence, these films and layers are protected against contamination by a residue of the photo resist layer, and irradiation of plasma during removal of the photo resist layer does not introduce a defect into these films and layers. As described above, when the photo resist layer is formed on the silicon film 30, a residue or defect can be removed at the step of thermally oxidizing the silicon film 30.

Although the foregoing has described the fifth preferred embodiment in relation to an example that there are the two types of peripheral transistors 501 and 502 with different thickness of the gate oxide film, this embodiment is also applicable to the case that three or more types of peripheral transistors are included.

As clearly described above, with the manufacturing method according to the present invention, it is possible to prevent contamination of an ONO film by a residue of a resist, and therefore, to obtain a semiconductor memory with excellent reliability.

Further, since no plasma is irradiated upon the ONO film, characteristics of elements are excellent in the semiconductor memory.

Further, it is possible to prevent a defect created in a silicon nitride film due to bird's beak. It is also possible to obtain a semiconductor memory with excellent characteristics of elements, and to reduce the size of the semiconductor memory.

Further, it is possible to simultaneously form peripheral transistors contained in a peripheral circuit.

What is claimed is:

1. A method of manufacturing a semiconductor memory having a MONOS structure, comprising:
an ONO film forming step of depositing an ONO film comprised of a first silicon oxide film, a silicon nitride film, and a second silicon oxide film on a semiconductor substrate;
a step of forming a first conductive layer on said ONO film after said ONO film forming step;
a step of forming a resist mask on said first conductive layer;
an etching step of etching at least said first conductive layer, said second silicon oxide film and said silicon nitride film to thereby form a groove portion;
a step of implanting ions into said semiconductor substrate in a bottom portion of said groove portion to thereby form bit lines;
a step of depositing an insulation film on said semiconductor substrate and reducing the thickness of said insulation film by a CMP method to thereby leave said insulation film within said groove portion; and
a step of depositing a second conductive layer on said first conductive layer and said insulation film to thereby form a word line.

2. A manufacturing method according to claim 1 wherein said first conductive layer patterned using said resist mask is used as an etching mask in said etching step.

3. A manufacturing method according to claim 1 wherein said word line is comprised of said first conductive layer and said second conductive layer.

4. A manufacturing method according to claim 1 wherein said first conductive layer and said second conductive layer are made of the same material.

5. A manufacturing method according to claim 1 wherein said first conductive layer and said second conductive layer are made of one material selected from polycrystalline silicon and amorphous silicon.

6. A method of manufacturing a semiconductor memory having a MONOS structure, comprising:
an ONO film forming step of depositing an ONO film comprised of a first silicon oxide film, a silicon nitride film and a second silicon oxide film on a semiconductor substrate;
a first conductive layer forming step of forming a first conductive layer on said ONO film after said ONO film forming step;
a step of forming a silicon nitride layer on said first conductive layer;
a step of forming a resist mask on said silicon nitride layer;
an etching step of etching at least said silicon nitride layer, said first conductive layer, said second silicon oxide film and said silicon nitride film to form a groove portion;
a step of implanting ions into said semiconductor substrate in a bottom portion of said groove portion to form bit lines;
a step of depositing an insulation film on said semiconductor substrate and reducing the thickness of said insulation film by a CMP method using said silicon nitride layer as a stopper layer to leave said insulation film within said groove portion;
a step of removing said silicon nitride layer; and
a step of depositing a second conductive layer on said first conductive layer and said insulation film to form a word line.

7. A manufacturing method according to claim 6 wherein said silicon nitride layer patterned using said resist mask is used as an etching mask in said etching step.

8. A manufacturing method according to claim 6 wherein said word line is comprised of said first conductive layer and said second conductive layer, and the height from said semiconductor substrate to a top surface of said first conductive layer is smaller than the height from said semiconductor substrate to a top surface of said insulation film left within said groove portion.

9. A manufacturing method according to claim 6 wherein said first conductive layer and said second conductive layer are made of the same material.

10. A manufacturing method according to claim 6 wherein said first conductive layer and said second conductive layer are made of one material selected from polycrystalline silicon and amorphous silicon.

11. A method of manufacturing a semiconductor device comprising a semiconductor memory having a MONOS structure and a peripheral transistor, comprising:
a step of defining a semiconductor memory forming area and a peripheral transistor forming area on a semiconductor substrate;
a step of depositing a first silicon oxide film, a silicon nitride film and a silicon film in this order on said semiconductor substrate;
a step of forming a resist mask on said silicon film;
an etching step of etching said silicon film, said silicon nitride film and said first silicon oxide film in said peripheral transistor forming area;
an oxidation step of oxidizing said semiconductor substrate in said peripheral transistor forming area to form a gate oxide film meanwhile oxidizing said silicon film to form a second silicon oxide film, so that an ONO film comprised of said first silicon oxide film, said silicon nitride film and said second silicon oxide film be formed; and
a step of forming a conductive layer on said-gate oxide film and said ONO film after said oxidation step.

12. A manufacturing method according to claim 11 wherein said silicon film patterned using said resist mask is used as an etching mask in said etching step.

13. The manufacturing method according to claim 11 wherein said oxidation step is a thermal oxidation step.

14. A manufacturing method according to claim 11 wherein said silicon film is comprised of a polycrystalline silicon film.

15. A manufacturing method according to claim 11, further comprising a step of forming a silicon nitride layer on said conductive layer.
